(19) United States
(12) Patent Application Publication
(10) Pub. No.: US 2012/0033358 A1
(43) Pub. Date: Feb. 9, 2012

(54) MOUNTING APPARATUS FOR POWER SUPPLY

(75) Inventors: YUN-LUNG CHEN, Tu-Cheng (TW); QUAN-GUANG DU, Shenzhen City (CN); CHUNG CHAI, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 12/978,138

(22) Filed: Dec. 23, 2010

(30) Foreign Application Priority Data
Aug. 4, 2010 (CN) 201010245106.X

(51) Int. Cl. H05K 5/00

(52) U.S. Cl. 361/679.01

(57) ABSTRACT

An assembly includes an enclosure, a mounting plate, and a power supply unit. The enclosure includes a rear plate and a side plate perpendicular to the rear plate. The rear plate defines an opening. The mounting plate is mounted on the side plate, and located adjacent the opening. The mounting plate includes a stop piece and a support piece. The stop piece is located in a vertical plane. The support piece is located in a horizontal plane. The power supply unit includes a front wall and a bottom wall. The power supply unit is located in the enclosure in alignment with the opening. The support piece supports the bottom wall of the power supply unit, and the stop piece abuts the front wall of the power supply unit. The power supply unit is configured to be removed from the enclosure through the opening.

### BACKGROUND

1. Technical Field

The present disclosure relates to mounting apparatuses for power supplies, and particularly to a mounting apparatus for readily and securely attaching a power supply to an electronic device.

2. Description of Related Art

Low-voltage direct current power is required for electronic components in an electronic device, such as motherboards and hard disk drives in a computer. A power supply is often mounted in an enclosure of the electronic device for converting alternating current to direct current and supplying the direct current to the electronic components.

Usually, the power supply unit is mounted in the enclosure from an interior of the enclosure. However, because the interior of the enclosure is often over crowded, it is difficult to move the power supply unit. Further, when the power supply unit is moved in the interior of the enclosure, the power supply unit often comes in contact with other components in the enclosure, which may damage or destroy the power supply unit and other components.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and exploded view of a mounting apparatus and a power supply unit in accordance with one embodiment.

FIG. 2 is similar to FIG. 1, but viewed from another aspect.

FIG. 3 is an assembled view of the mounting apparatus and the power supply unit of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

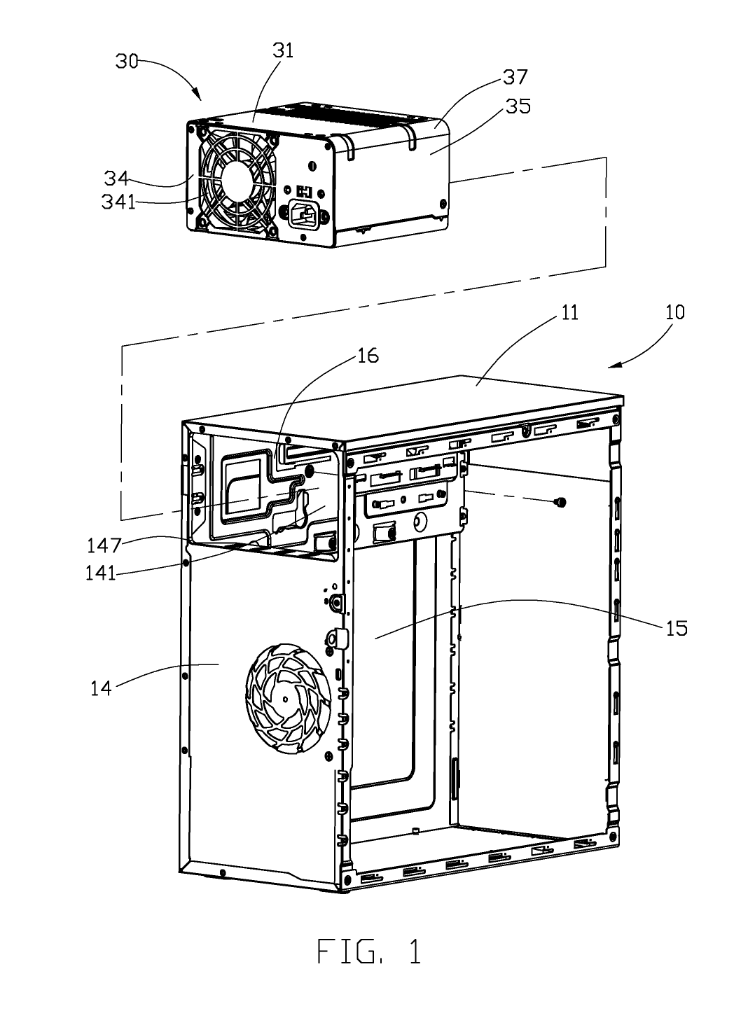

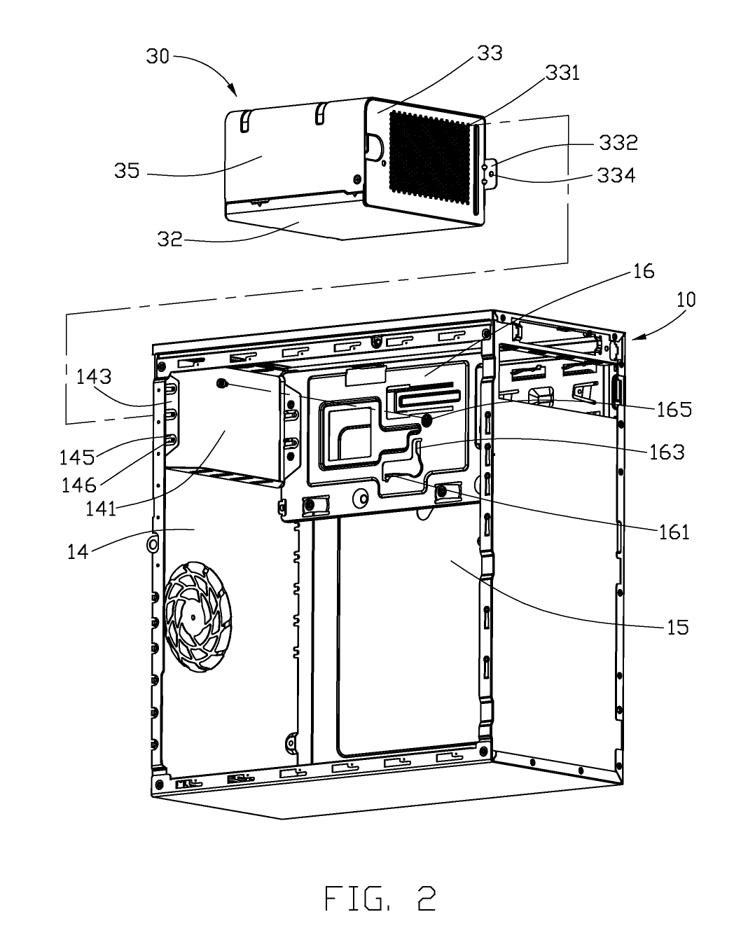

Referring to FIGS. 1 and 2, a mounting apparatus in accordance with an embodiment for mounting a power supply unit 30 includes an enclosure 10. The power supply unit 30 includes a top wall 31, a bottom wall 32, a front wall 33, a rear wall 34, and a pair of side walls 35. The front wall 33 defines a plurality of first vent holes 331. The rear wall 34 defines a plurality of second vent holes 341. A mounting piece 332 is connected to a connection portion of the front wall 33 and a side wall 35. The mounting piece 332 is perpendicular to the front wall 33. The mounting piece 322 and the side wall 35 are located in the same plane. A mounting hole 334 is defined in the mounting piece 332. A connection portion of the top wall 31 and each side wall 35 is an arc shaped bridge corner 37. A connection portion of the bottom wall 32 and each side wall 35 is an arc shaped bridge corner 37.

The enclosure 10 includes a top plate 11, a rear plate 14, and a side plate 15. The top plate 11, the rear plate 14, and the side plate 15 are perpendicular to each other. The rear plate 14 defines an appropriately rectangular opening 141. A size of the opening 141 is slightly larger than that of the front wall 33 of the power supply unit 30. Four restricting pieces 143 are connected to four edges of the opening 141. The restricting pieces 143 are perpendicular to the rear plate 14. Each restricting piece 143 defines a plurality of grooves 145. An elastic finger 146 is located in each groove 145 for shielding electro magnetic interference (EMI). The elastic finger 146 is slightly titled up from the restricting piece 143. Four corners of the opening 141 are round corners 147 for accommodating with the four bridge corners 37 of the power supply unit 30.

A mounting plate 16 is mounted on the side plate 15. The mounting plate 16 is located adjacent the opening 141. The mounting plate 16 has a horizontal support piece 161 and a vertical stop piece 163. Both the support piece 161 and the stop piece 163 are perpendicular to the side plate 15. The support piece 161 and a lower edge of the opening 141 are located in a horizontal plane. The mounting plate 16 defines a securing hole 165 corresponding to the mounting hole 334 of the power supply unit 30.

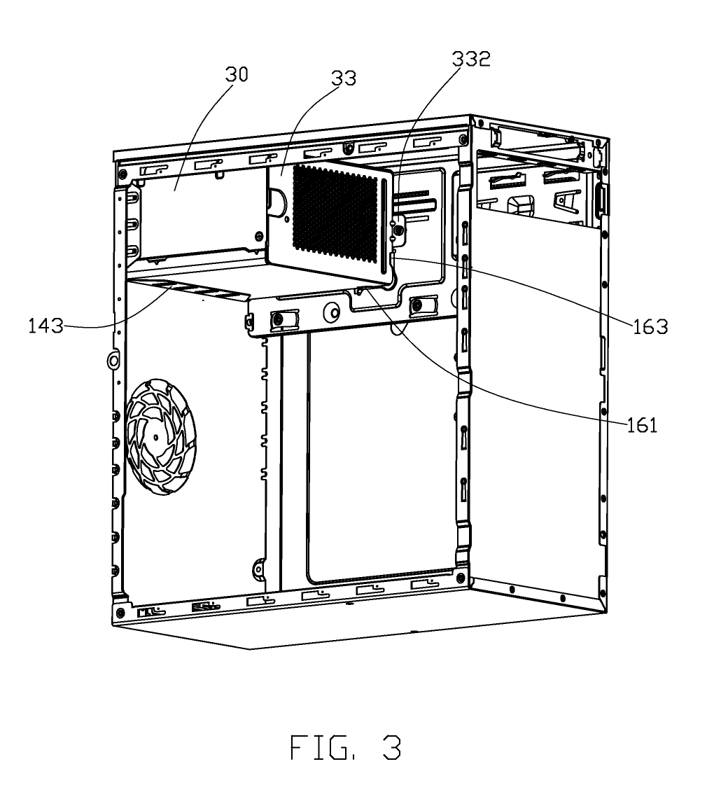

Referring to FIGS. 1 to 3, to mount the power supply unit 30 in the enclosure 10, the front wall 33 of the power supply unit 30 is in alignment with the opening 141. The power supply unit 30 is moved in the enclosure 10 through the opening 141. Because the bridge corners 37 of the power supply unit 30 and the round corners 147 of opening 141 are in an arc shape, tt is smooth for the power supply unit 30 moving in the opening 141. Simultaneously, the four restricting pieces 143 abut the top wall 31, the bottom wall 32, and the pair of side walls 35 of the power supply unit 30. The elastic fingers 146 of the restricting pieces 143 are in contact with outer surface of the power supply unit 30 to achieve EMI shielding. The restricting piece 143, which is connected to the lower edge of the opening 141, supports the power supply unit 30 thereon. The power supply unit 30 is moved until the support piece 161 supports the power supply unit 30 and the stop piece 163 abuts the front wall 33 of the power supply unit 30. In this position, the mounting hole 334 is in alignment with the securing hole 165. A fastener is mounted in the mounting hole 334 and the securing hole 165 to secure the power supply unit 30 in the enclosure 10.

When the power supply unit 30 needs to be disassembled, the fastener is detached, and the power supply unit 30 can be slid from the opening 141 and out of the enclosure 10.

In the mounting apparatus for power supply unit 30, the power supply unit 30 can be inserted in the enclosure 10 or removed from the enclosure 10 through the opening 141. Therefore, the power supply unit 30 avoids contact with other components in the enclosure 10 when the power supply unit 30 is moved.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An assembly comprising:
an enclosure comprising a rear plate and a side plate perpendicular to the rear plate, and the rear plate defining an opening;
a mounting plate, mounted on the side plate, located adjacent the opening; the mounting plate comprises a stop piece and a support piece; the stop piece is located in a vertical plane, and the support piece is located in a horizontal plane; and
a power supply unit comprising a front wall and a bottom wall, wherein the power supply unit is located in the enclosure in alignment with the opening, the support piece supports the bottom wall of the power supply unit, and the stop piece abuts the front wall of the power supply unit; and the power supply unit is configured to be removed from the enclosure through the opening.

2. The assembly of claim 1, wherein the opening comprises a plurality of round corners, and the power supply unit comprises a plurality of bridge corners, shapes of the plurality of bridge corners correspond to those of the plurality of round corners, and the plurality of round corners corresponds to the plurality of bridge corners.

3. The assembly of claim 1, wherein a plurality of restricting pieces is connected to edges of the opening, and the plurality of restricting pieces is perpendicular to the rear plate and abuts the power supply unit.

4. The assembly of claim 3, wherein each of the plurality of restricting pieces defines a plurality of grooves thereon, and an elastic finger is located in each of the plurality of grooves.

5. The assembly of claim 4, wherein each elastic finger slightly protrudes and contacts the power supply unit.

6. The assembly of claim 3, wherein one of the plurality of restricting pieces, which is connected to a lower edge of the opening, supports the power supply unit thereon.

7. The assembly of the claim 1, wherein the mounting plate defines a securing hole; a mounting piece is perpendicularly connected to the front wall of the power supply unit; and the mounting piece defines a mounting hole, the securing hole is in aligned with the mounting hole, and a fastener is mounted in the securing hole and the mounting hole.

8. An assembly, comprising:
an enclosure comprising a rear plate, the rear plate defining an opening, and the opening comprising a plurality of round corners; and
a power supply unit comprising a plurality of bridge corners, shapes of the plurality of bridge corners corresponding to those of the plurality of round corners, wherein the power supply unit is located in the enclosure in alignment with the opening; and the power supply unit is configured to be removed from the enclosure through the opening.

9. The assembly of claim 8, wherein a plurality of restricting pieces is connected to edges of the opening, the plurality of restricting pieces is perpendicular to the rear plate, and abuts the power supply unit.

10. The assembly of claim 9, wherein each of the plurality of restricting pieces defines a plurality of grooves thereon, and an elastic finger is located in each of the plurality of grooves.

11. The assembly of claim 10, wherein the elastic fingers are in contact with the power supply unit.

12. The assembly of claim 9, wherein one of the plurality of restricting pieces, which is connected to a lower edge of the opening, supports the power supply unit thereon.

13. The assembly of claim 8, wherein the enclosure comprises a side plate that is perpendicular to the rear plate; a mounting plate is mounted on the side plate, the mounting plate comprises a stop piece that is located perpendicular to the side plate; and the stop piece abuts a front wall of the power supply unit.

14. The assembly of claim 13, wherein the mounting plate comprises a support piece, the support piece is located perpendicular to the stop piece, and the support piece supports the power supply unit thereon.

15. The assembly of the claim 13, wherein the mounting plate defines a securing hole; a mounting piece is perpendicularly connected to the front wall of the power supply unit; and the mounting piece defines a mounting hole, the securing hole is in aligned with the mounting hole, and a fastener is mounted in the securing hole and the mounting hole.
